(19) United States
(12) Patent Application Publication
(10) Pub. No.: US 2024/0281577 A1
(43) Pub. Date: Aug. 22, 2024

(54) DISCONTINUITY MODELING OF COMPUTING FUNCTIONS

(71) Applicants: Adobe Inc., San Jose, CA (US); The Trustees of Princeton University, Princeton, NJ (US)

(72) Inventors: Connelly Stuart Barnes, Seattle, WA (US); Yuting Yang, Princeton, NJ (US); Adam Finkelstein, Princeton, NJ (US); Andrew Bensley Adams, Lafayette, CA (US)

(73) Assignees: Adobe Inc., San Jose, CA (US); The Trustees of Princeton University, Princeton, NJ (US)

(21) Appl. No.: 18/170,735

(22) Filed: Feb. 17, 2023

(51) Int. Cl. G06F 30/27; G06N 3/084

(52) U.S. Cl. CPC G06F 30/27; G06N 3/084

(57) ABSTRACT

Discontinuity modeling techniques of computing functions of a program are described. In one example, a program has a computing function that includes a discontinuity. An input is received by the data modeling system that identifies an axis. A plurality of samples is then generated by the data modeling system along the axis based on an output of the program. The samples are then used as a basis by the data modeling system to generate a data model that models the discontinuity. The data model includes, in one example, one or more gradients and models the discontinuity using a 1D box kernel.

### BACKGROUND

Automatic differentiation is a technique usable by a computing device to evaluate a derivative of a computing function of a program, i.e., a computer program. These techniques are usable by the computing device to implement a wide range of computer functionality, examples of which include machine learning, image processing, computing optimizations, and so forth. Conventional automatic differentiation techniques, however, assume the computing function is continuous and therefore are inaccurate and often fail in real world usage scenarios.

### SUMMARY

Discontinuity modeling techniques of computing functions of a program are described. In one example, a program has a computing function that includes a discontinuity, e.g., an if/else branch. An input is received by the data modeling system that identifies an axis, e.g., via a user input based on domain knowledge. A plurality of samples is then generated by the data modeling system along the axis based on an output of the program. The program, for instance, is executable by the data modeling system to change values of one or more parameters, an output of which is used to form the samples along the axis. The samples are then used as a basis by the data modeling system to generate a data model that models the discontinuity. The data model includes, in one example, one or more gradients and models the discontinuity, e.g., using a 1D box kernel.

This Summary introduces a selection of concepts in a simplified form that are further described below in the Detailed Description. As such, this Summary is not intended to identify essential features of the claimed subject matter, nor is it intended to be used as an aid in determining the scope of the claimed subject matter.

### BRIEF DESCRIPTION OF THE DRAWINGS

The detailed description is described with reference to the accompanying figures. Entities represented in the figures are indicative of one or more entities and thus reference is made interchangeably to single or plural forms of the entities in the discussion.

FIG. 1 is an illustration of an environment in an example implementation that is operable to employ discontinuity modeling techniques described herein.

FIG. 2 depicts a system in an example implementation in which a data modeling system and data model execution system of FIG. 1 are employed in support of machine learning.

FIG. 3 depicts a system in an example implementation showing operation of the data modeling system of FIG. 1 in greater detail.

FIGS. 4 and 5 depict example implementations of a Heaviside step function and a Dirac delta distribution, respectively.

FIG. 6 depicts an example implementation of sampling the discontinuity using two evaluations to form two samples.

FIG. 7 depicts an example implementation of generating the modeled discontinuity as a box kernel approximation using a 1D box kernel by the discontinuity modeling module.

FIG. 8 depicts an example implementation of generating the modeled discontinuity as a box kernel approximation using a 1D box kernel.

FIG. 9 is a flow diagram depicting an example procedure of discontinuity modeling of computing functions.

FIG. 10 depicts an example implementation of visualizing different options for how to combine multiple sampling axes.

FIG. 11 illustrates an example system including various components of an example device that can be implemented as any type of computing device as described and/or utilize with reference to FIGS. 1-10 to implement embodiments of the techniques described herein.

### DETAILED DESCRIPTION

### Overview

Gradients are relied upon to implement a wide range of computer functionality, examples of which include machine learning, graphics and vision optimization, audio processing, and so forth. Gradients are computable, automatically and without user intervention, as an expression of explicit functions of given parameters of a computing function of a program. The gradients, for instance, are computed as derivates based on a sequence of elementary arithmetic operations and elementary functions utilized by the program during execution.

Conventional techniques to compute the gradients, however, assume that the computing functions are continuous with respect to input parameters. As such, these conventional techniques are inaccurate and often fail when confronted when discontinuities are included as part of the computing function.

The computing function, for instance, is configurable to include an if/else branch such that operation “X” is performed if a criterion is met and operation “Y” is performed if the criterion is not met. The discontinuity therefore causes an abrupt change in values output by the computing function as opposed to continuous variation expressed using a continuous computing function. Because of this, functionality of a computing device that relies on these techniques such as object boundary modeling and detection, visibility, image segmentation, physics simulation, and so forth achieve inaccurate results and can fail (e.g., to optimize functions used by this functionality) when encountering a computing function having a discontinuity.

To address these technical challenges involving computing device operation, techniques are described that support discontinuity modeling of computing functions. In one example, these techniques begin by receiving a program by a data modeling system. The program has a computing function that includes a discontinuity, e.g., an if/else branch as described above.

An input is also received by the data modeling system that identifies an axis. The axis is selected based on an ability to detect the discontinuity via the axis. An axis of “time,” for instance, is selected for audio or physics simulation programs. The input is receivable by the data modeling system via a user input (e.g., based on domain knowledge) or performed automatically and without user intervention by the data modeling system, e.g., based on a data type. The axis, for instance, is definable as a linear combination of the parameters. As a result, a computational challenge of sampling discontinuities in high dimensions is reduced by placing samples along the selected axis.

A plurality of samples is then generated by the data modeling system along the axis based on an output of the program. The program, for instance, is executable by the data modeling system to change values of parameters, an output of which is used to form the samples along the axis. The samples are then used as a basis by the data modeling system to generate a data model that models the discontinuity. The data model includes, in one example, one or more gradients and models the discontinuity, e.g., using a 1D box kernel. In an example, this is performed using pairs of samples to estimate gradients by the data modeling system between the samples and thus model the discontinuity. The data model, once generated, is usable to support a variety of functionalities, including image processing, in support of a backpropagation operation as part of machine learning, and so forth. In this way conventional challenges are overcome thereby improving data model generation and computing device functionality that relies on the data model. Further discussion of these and other examples is included in the following sections and shown in corresponding figures.

In the following discussion, an example environment is described that employs the techniques described herein. Example procedures are also described that are performable in the example environment as well as other environments. Consequently, performance of the example procedures is not limited to the example environment and the example environment is not limited to performance of the example procedures.

### Example Environment

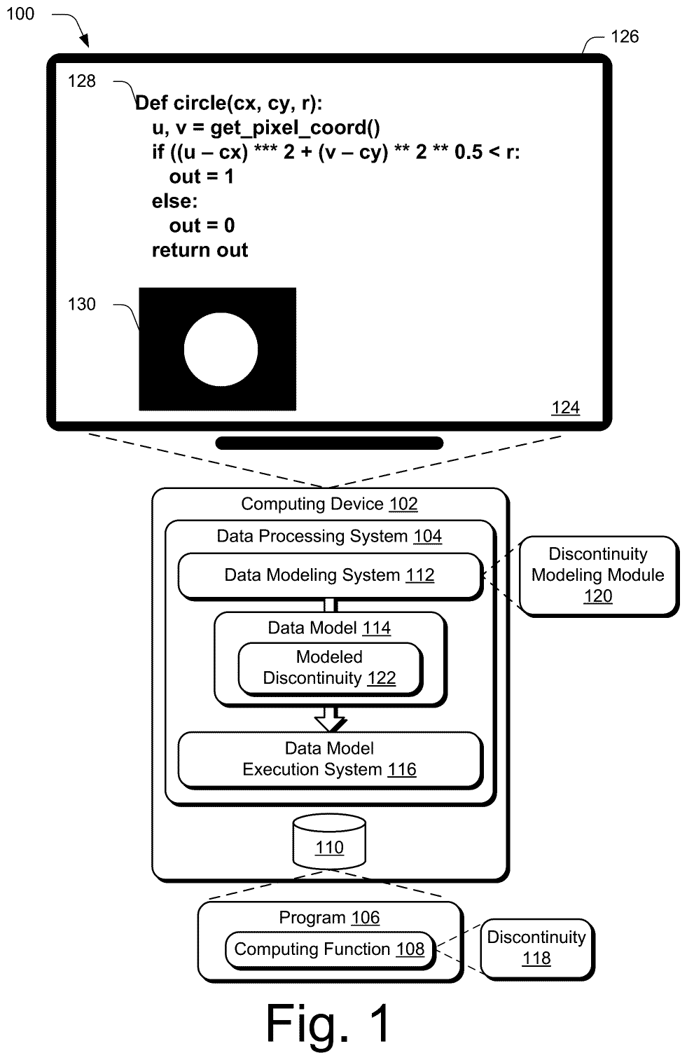

FIG. 1 is an illustration of a digital medium environment 100 in an example implementation that is operable to employ techniques described herein. The illustrated environment 100 includes a computing device 102, which is configurable in a variety of ways.

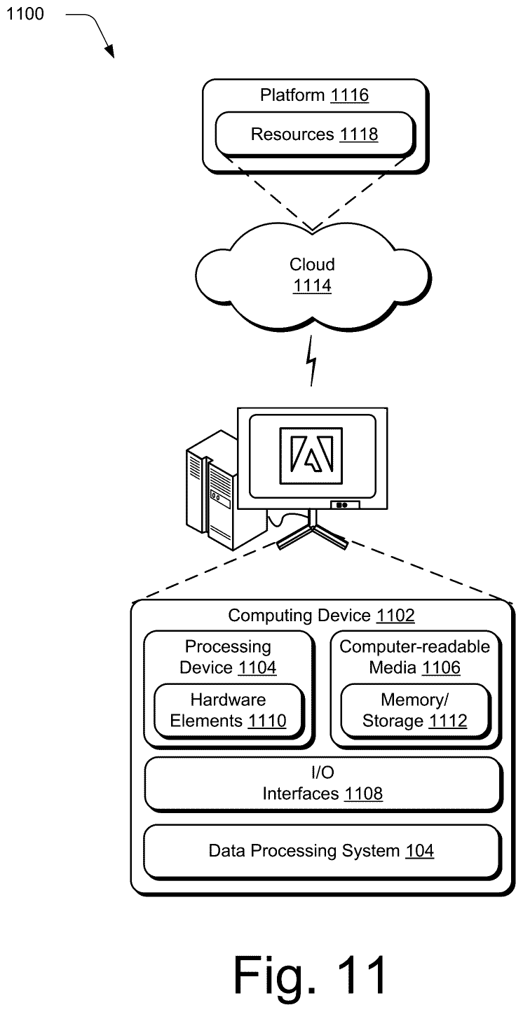

The computing device 102, for instance, is configurable as a desktop computer, a laptop computer, a mobile device (e.g., assuming a handheld configuration such as a tablet or mobile phone), and so forth. Thus, the computing device 102 ranges from full resource devices with substantial memory and processor resources (e.g., personal computers, game consoles) to a low-resource device with limited memory and/or processing resources (e.g., mobile devices). Additionally, although a single computing device 102 is shown, the computing device 102 is also representative of a plurality of different devices, such as multiple servers utilized by a business to perform operations “over the cloud” as described in FIG. 11.

The computing device 102 is illustrated as including a data processing system 104. The data processing system 104 is configurable to implement a wide range of functionality, examples of which include a program 106 having a computing function 108 that is executable by a processing device (e.g., a central processing unit, graphics processing unit) and is storable in a computer-readable storage media 110. Functionality of the data processing system 104 is also configurable as whole or part via functionality available via a network, such as part of a web service or “in the cloud” as further described in relation to FIG. 11.

The data processing system 104 includes a data modeling system 112 (e.g., implemented as a compiler) that is representative of functionality to generate a data model 114 of the program 106, e.g., as one or more gradients. The data model 114 is then usable as a basis to perform one or more operations by a data model execution system 116. Many graphics and vison optimization features, for instance, rely on gradients. Therefore, in order to support these techniques, the data modeling system 112 generates the data model 114 as gradients to convert outputs that are generated through execution of explicit functions using given parameters. The data model 114, configured using gradients, are computed by the data modeling system 112 as derivates based on an output of execution of a sequence of elementary arithmetic operations and elementary functions utilized by the program 106 during execution. The data model execution system 116 then employs the data model 114 to implement respective functionality, e.g., object visibility, for use in shader programs, and so forth.

Conventional techniques that are utilized to generate the gradients assume that the computing functions are continuous with respect to input parameters. As such, these conventional techniques are inaccurate and often fail when confronted when the computing function 108 includes a discontinuity 118. For example, programs 106 that are used to implement shader rendering functionality intrinsically rely on discontinuities. As a result, the conventional techniques used to automatically generate gradients often fail in support of this functionality.

To address these technical challenges and improve computing device 102 operation, a discontinuity modeling module 120 is employed by the data modeling system 112 to generate a modeled discontinuity 122 as part of the data model 114. In this way, the modeled discontinuity 122 supports functionality in optimization tasks that improve accuracy that is not possible in conventional techniques, e.g., for object silhouettes Z ordering in rendering operation, and so on.

In the illustrated user interface 124 as displayed by a display device 126, for instance, an example program 128 is depicted to draw a circle 130. The example program 128 includes a discontinuous if/else branch to test whether a pixel is inside or outside the circle. In scenarios used to optimize a radius and circle position to match the circle 130, conventional techniques are incapable of converging because conventional techniques output zero gradients for these parameters. In the techniques described herein, however, the data model 114 includes the modeled discontinuity 122 and thus supports an ability to optimize a radius and circle position in the illustrated example. The data model 114 and modeled discontinuity 122 are usable to support a variety of functionality, further discussion of which is included in the following description and shown in corresponding figures.

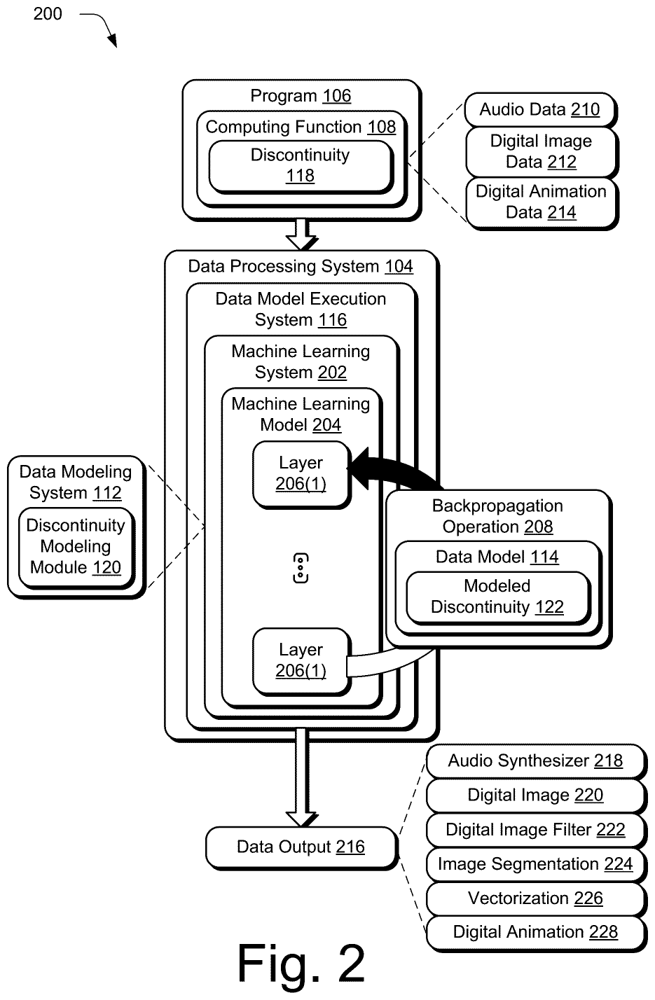

FIG. 2 depicts a system 200 in an example implementation in which the data modeling system 112 and the data model execution system 116 of FIG. 1 are employed in support of machine learning. The data processing system 104 is illustrated as including a machine learning system 202 that implements a machine learning model 204 having a plurality of layers, examples of which are illustrated as layer 206(1), . . . , layer 206(N).

The machine learning model 204 is configurable in a variety of ways, an example of which includes a neural network. The neural network is trained and retrained by processing samples from an input to form probability-weighted associations between the input and a result. An error between the input and the result is then used to adjust the weights. As part of this, a backpropagation operation 208 is utilized between the layers 206(1)-206(N) to adjust connection weights to compensate for error found during learning. The backpropagation operation 208 calculates a gradient (e.g., a derivative) of a cost function associated with a given state with respect to the weights. Therefore, backpropagation refers to a process of training the machine learning model 204 using the backpropagation operation 208, each of which involves computing a gradient to perform a gradient descent operation. Backpropagation techniques described herein also support scenarios in which the machine-learning model itself is discontinuous, e.g., an argmax at an output layer, a loss that is discontinuous, or the neural network itself can is binarized such that each parameter is either a zero or a one.

In this example, the discontinuity modeling module 120 is employed as part of the data modeling system 112 to generate a data model 114 as one or more gradients. Generation of the data model 114 by the data modeling system 112 is therefore used in this example to compute gradients in support of the backpropagation operation 208. Further, the data model 114 is configured to include the modeled discontinuity 122, which is not possible in conventional techniques.

In this way, accuracy in training and use of the machine learning model 204 is improved in support of a wide variety of functionality. The data processing system 104, for instance, is configurable to support a variety of data types, examples of which include audio data 210, digital image data 212, digital animation data 214 and other data including textual data, data signals, and so forth. The data processing system 104 then processes this data using the machine learning model 204 that is configurable to leverage a modeled discontinuity within the data model 114 as part of machine learning implemented by the machine learning model 204. Training and retraining of the machine learning model 204 using the data model 114 is performable to generate a variety of data output 216 types, examples of which include use in an audio synthesizer 218, digital image 220 generation, digital image filter 222, image segmentation 224, vectorization 226, digital animation 228, and so forth. Further discussion of operation of the data modeling system 112 and discontinuity modeling module 120 to generate the data model 114 having the modeled discontinuity 122 is included in the following section and shown in corresponding figures.

In general, functionality, features, and concepts described in relation to the examples above and below are employed in the context of the example procedures described in this section. Further, functionality, features, and concepts described in relation to different figures and examples in this document are interchangeable among one another and are not limited to implementation in the context of a particular figure or procedure. Moreover, blocks associated with different representative procedures and corresponding figures herein are applicable together and/or combinable in different ways. Thus, individual functionality, features, and concepts described in relation to different example environments, devices, components, figures, and procedures herein are usable in any suitable combinations and are not limited to the particular combinations represented by the enumerated examples in this description.

### Discontinuity Modeling Techniques

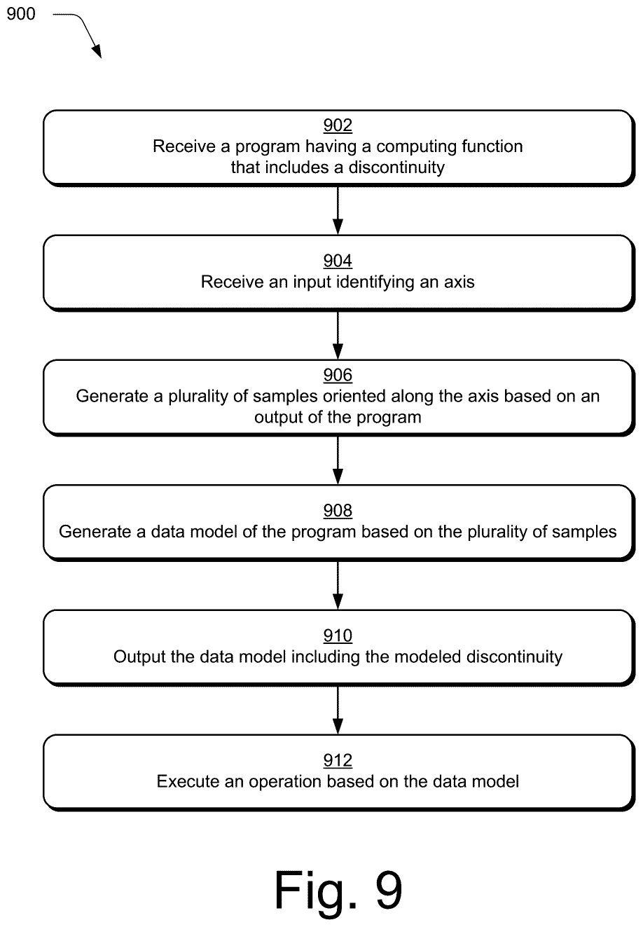

The following discussion describes techniques that are implementable utilizing the previously described systems and devices. Aspects of each of the procedures are implemented in hardware, firmware, software, or a combination thereof. The procedures are shown as a set of blocks that specify operations performed by one or more devices and are not necessarily limited to the orders shown for performing the operations by the respective blocks. In portions of the following discussion, reference is made to FIGS. 1-8 in parallel with an example procedure 900 of FIG. 9.

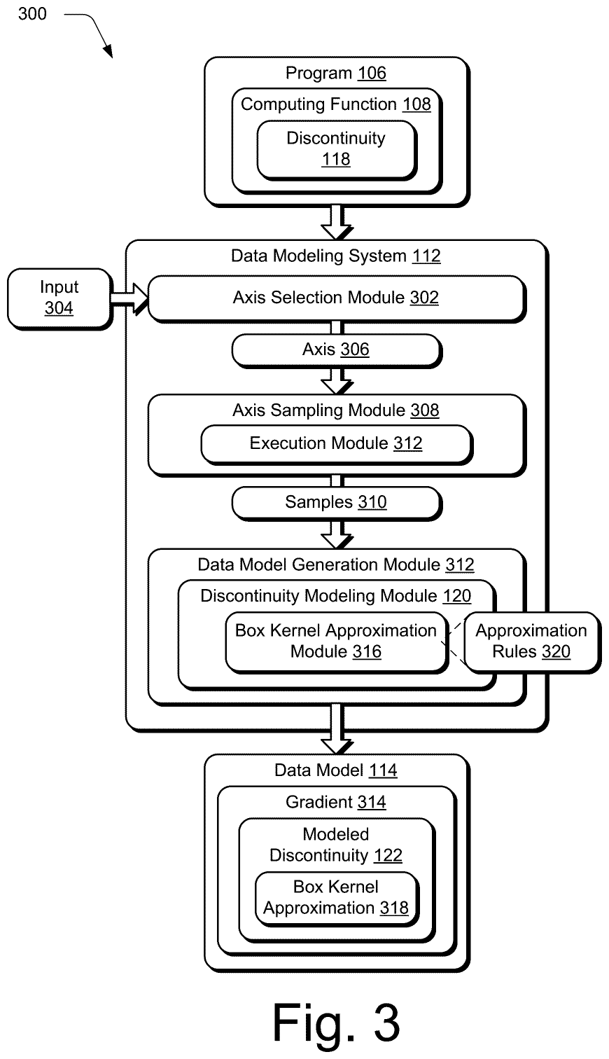

FIG. 3 depicts a system 300 in an example implementation showing operation of the data modeling system 112 of FIG. 1 in greater detail. The data modeling system 112 begins by receiving a program 106 having a computing function 108 that includes a discontinuity 118 (block 902). A discontinuity is a point, at which, an output of the computing function 108 is discontinuous, examples of which include infinite and jump discontinuities. The program 106, for instance, is configurable to include and if/else branch such that operation “X” is performed if a criterion is met and operation “Y” is performed if the criterion is not met. The discontinuity therefore causes an abrupt change in values output by the computing function as opposed to continuous variation expressed using a continuous computing function. As previously described, this causes errors in conventional automatic differentiation techniques that assume continuous values.

An axis selection module 302 receives an input 304 identifying an axis 306 (block 904). The axis 306 is used to address a computational challenge of sampling a discontinuity in a high dimensional space. In some real world scenarios, it has been identified as part of the techniques described herein that there are one or a few dimensions in a parameter space that influence a majority of parametric discontinuities, e.g., an axis of “time” for audio or physics simulation programs, two-dimensional image axes for shader programs, and so forth. As a result, a computational challenge of sampling discontinuities in the high dimensional space is reduced by placing samples along one or more of these axes, and thus reduces computational complexity to a lower dimension space. In the following discussion, this axis 306 is also referred to as a “sampling axis.”

In principle, a sampling axis is configurable as any arbitrary axis. This is performable without each discontinuity projecting to a single axis in order to implement the following functionality as long as discontinuities of interest project to this axis and thus a corresponding contribution to the gradient is included. The input 304 is configurable in a variety of ways, such as a user input received via a user interface based on domain knowledge (e.g., to use “time” for audio of physical simulation programs in the above example), detectable automatically and without user intervention (e.g., to use two-dimensional image axes for shader programs), and so forth.

An axis sampling module 308 is then utilized to generate a plurality of samples 310 oriented along the axis 306 based on an output of the program (block 906). The axis sampling module 308, for instance, changes values of one or more parameters of the computing function 108 and plots the outputs the corresponding axis 306. This is performable through execution of the program 106 by an execution module 308, e.g., to execute instructions specified by the program 106 for the computing function 108 and generate the samples 310 as outputs of operations performed based on the executed instructions.

The samples 310 are then passed as an input to a data model generation module 312 to generate a data model 114. The data model 114 is generated as including a modeled discontinuity 122 of the computing function 108 based on the samples (block 908) through use of a discontinuity modeling module 120. The data model generation module 312, for instance, generates the data model 114 using one or more gradients 314. The discontinuity modeling module 120 includes a box kernel approximation module 316 to generate the modeled discontinuity 122 as a box kernel approximation 318 based on one or more approximation rules 320. Further discussion of generating of the modeled discontinuity 122 as a box kernel approximation 318 is included in the following discussion and shown in corresponding figures.

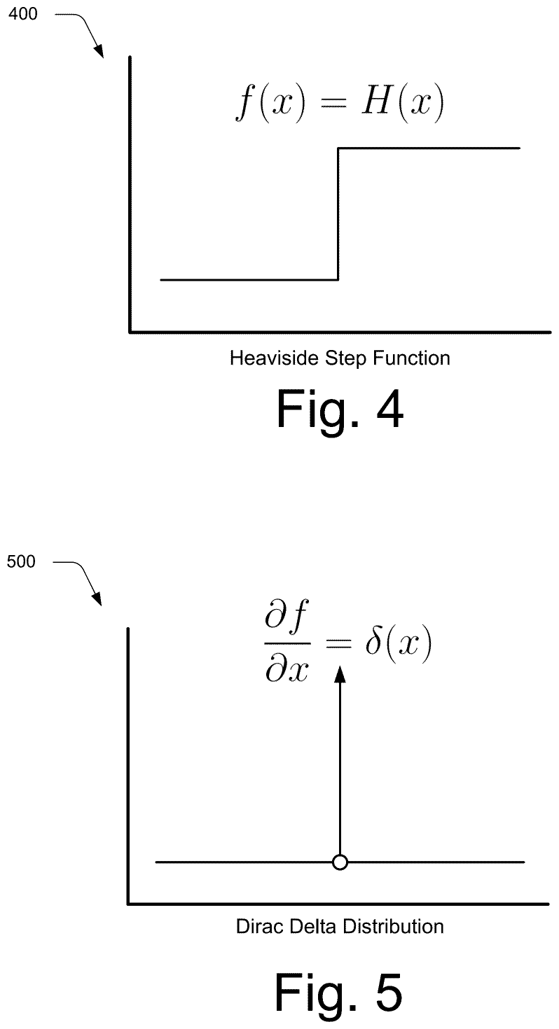

FIGS. 4 and 5 depict example implementations 400, 500 of a Heaviside step function and a Dirac delta distribution. The data model generation module 312 employs a framework that models the discontinuity 118 as compositions of a Heaviside step function. This is a 1D function that evaluates to “0” on one side and “1” on another side of a transition that defines the discontinuity. The function, for instance, maps values for an if/else branch in which values for a first branch are “zero” and values of a second branch are “1,” e.g., based on whether a condition of the “if” is met.

Following a theory of distributions, a derivative of the Heaviside step function of FIG. 4 is a Dirac delta distribution as shown in FIG. 5. The Dirac delta distribution evaluates to infinity at an origin (i.e., the transition) and a value of “0” elsewhere. The Dirac delta distribution is approximated by function sequences that integrate to a value of “1” and approach a distribution of the limit.

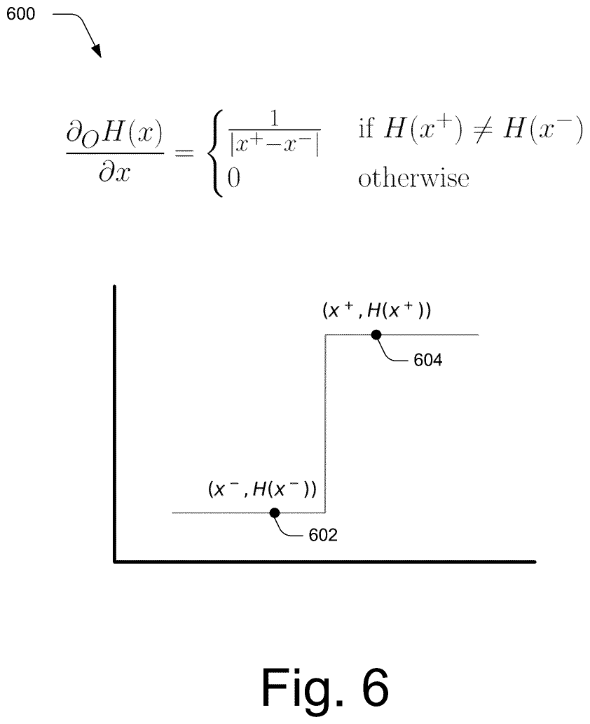

FIG. 6 depicts an example implementation 600 of sampling the discontinuity 118 using two evaluations to form two samples. Because the discontinuity 118 is sampled with a zero probability at a single point, the axis sampling module 308 is configured to generate a pair of samples along the axis 306. In this example, a first sample is labeled as “x⁺” and a second sample as labeled as “x⁻” The data model generation module 312 then approximates a gradient (i.e., the derivative) with respect to this pair of samples as further described in the following example.

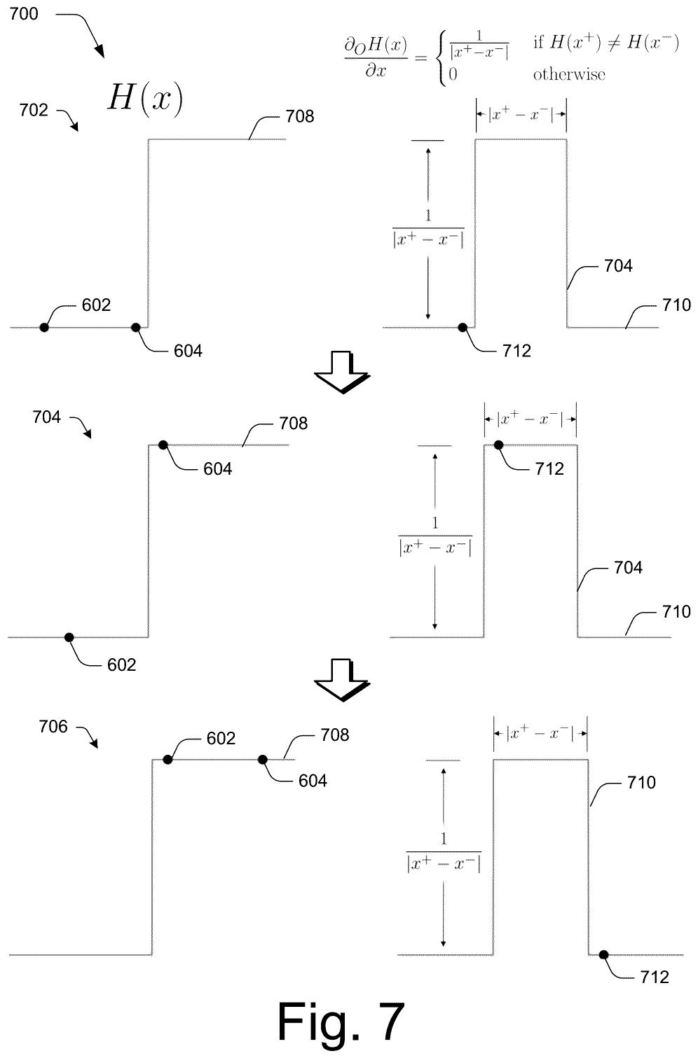

FIG. 7 depicts an example implementation 700 of generating the modeled discontinuity 122 as a box kernel approximation 318 using a 1D box kernel by the discontinuity modeling module 120. This example is depicted using a first stage 702, a second stage 704, and a third stage 706. A Heaviside step function 708 and a corresponding gradient 710 are depicted. Pairs of samples including the first sample 602 and the second sample 604 are taken successively at the first, second, and third stages 702, 704, 706 and used to generate values 712 of the gradient 710.

This is performed by differentiating the computing function 108 after pre-filtering the function with a 1D box kernel. The distance between the two evaluation sites (e.g., the first and second samples 602, 604) defines a size of the box kernel. By moving the evaluation sites and corresponding samples along the X axis, the gradient 710 of the Heaviside step function 708 has a piecewise constant box shape, which integrates to “1” and has an area of “1.” This approximates the Dirac delta in the limit when the kernel size goes to zero.

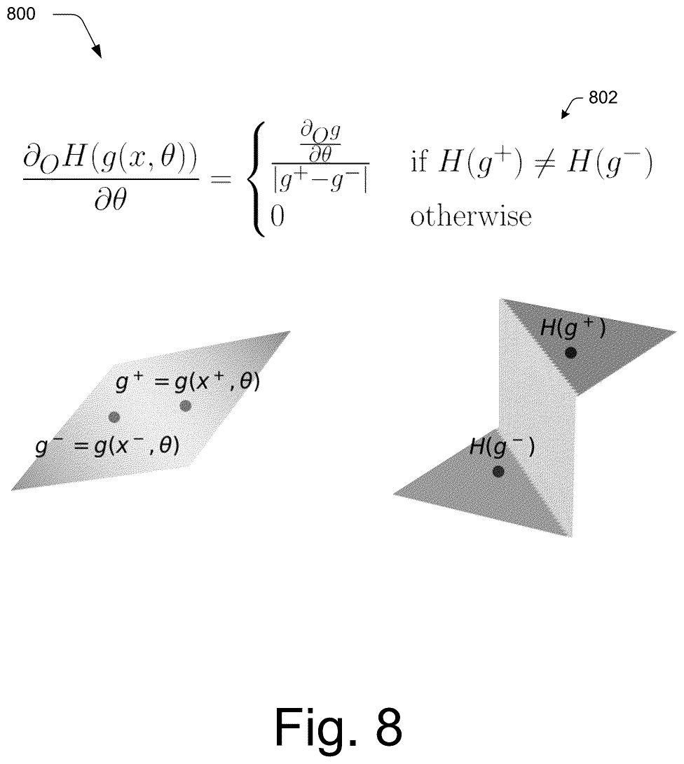

FIG. 8 depicts an example implementation 800 of generating the modeled discontinuity 122 as a box kernel approximation 318 using a 1D box kernel by the discontinuity modeling module 120 for a plurality of parameters. In some real world scenarios, discontinuities in programs 106 depend on multiple variables. Accordingly, for computational efficiency the data modeling system 112 in this example pre-filters samples using a 1D box kernel as part of generating the gradients.

The 1D box kernel supports orientation along any axis, and in an implementation is oriented along an axis, from which, a greatest number of discontinuities of interest depends. In the illustrated example the 1D box kernel is oriented along the X axis. An example of the Heaviside step function is illustrated as configured as a function of another 2D function “g(x, theta),” which is sampled along the X axis while keeping theta fixed. Similar to the previous examples, a pair of samples are generated as “g⁺” and “g⁻” In a multivariate case, the Dirac Delta's scaling property is applied to derive a correct result. A final rule 802 is depicted for differentiating the step functions, which is equivalent to differentiating the function after pre-filtering with a box kernel.

Returning again to FIG. 3, the approximation rules 320 are configured to correctly differentiate discontinuities, which includes multiplication (*), addition (e.g., sum), step “H(g),” and function composition “f(g).” Correctness of the rules is verifiable by differentiating a function after pre-filtering with the 1D box kernel using two evaluation sites, one at each endpoint.

Once generated, the data model 114 is output as including the modeled discontinuity 122 (block 910). An operation is then executed by the computing device using the data model 114 (block 912). A variety of operations are configurable to leverage the data model 114 as previously described in relation to FIG. 2. An example of use of the data model 114 in a shader scenario is described in the following section and shown in corresponding figures.

### Implementation Example

Gradient-based optimizations are widely used to obtain parameter settings for graphics or vision programs. These programs typically include both continuous and discontinuous operations, such as branching. Differentiating the parametric discontinuities supports computational tasks such as optimizing object edges, visibility, and ordering. As described above, conventional automatic differentiation techniques treat programs as continuous and ignore gradients due to discontinuities.

Accordingly, in the following discussion an efficient compiler-based approach by the data processing system 104 is described to approximate differentiate arbitrary discontinuous programs. Gradient rules are introduced that generalize differentiation to work in a setting where there is a single discontinuity in a local neighborhood. The rule approximates a gradient (e.g., prefiltered) over a box kernel oriented along a 1D sampling axis. In the following discussion, these techniques are evaluated on procedural shader programs, where the task is to optimizes unknown parameters in order to match a target image. The compiler outputs gradient programs. Representation of data model 114 for a program supports interactive editing and animate optimized programs through a core language (GLSL) backend, which otherwise is cumbersome in other conventional representations such as triangle meshes or vector art.

The compiler, for instance, as implemented by the data processing system 104 takes as an input of an arbitrary domain specific language (DSL) program and approximates the gradient by pre-filtering a 1D box kernel along sampling axes. Approximations along multiple sampling axes are combinable. The gradients are then applicable to optimization tasks that find optimal parameters for a shader program to best match a reference image. In an implementation, per-pixel random noise is added to parameters, on which, discontinuities depend (e.g., Dirac parameters), as this encourages observance of the discontinuities in an increased number of pixel locations. The data model 114 (as a program representation) is output to a core language (GLSL) backend with optimized parameters, which supports interactive animation.

The compiler approximates the gradient over a 1D box kernel, where the kernel orientation follows the sampling axis. Approximations leveraged by the compiler to generate the data model 114 include:
There is a single discontinuity between each pair of samples;
Function values and partial derivatives within the computation at a pair of samples are usable to estimate gradients at locations between the samples; and
Discontinuities can be projected to the sampling axis.

The following description also discusses how to evaluate a quality of the gradient and how to generate efficient GPU code for the gradients. The applicability of the gradient program in the domain of procedural shader programs is described in the following example to optimize parameters of shader programs to match reference images.

Approximate derivative rules are described that are applicable to general programs. For a subset of programs, approximation error is bounded by a first order term to a size of the kernel. Additionally, a system implementing these techniques is configured to efficiently carry out practical applications in shader programs.

In an example as described above, ƒ (x, θ)=H(x+θ), where x is a sampling axis that is used to sample discontinuities and θ is a parameter used to obtain a derivative. H is a Heaviside step function that evaluates to 1 when x+θ≥0, and 0 otherwise. Mathematically, the gradient of a Heaviside step function is a Dirac delta distribution δ as described above, which informally evaluates to +∞ at the discontinuity, 0 otherwise, and formally is defined as a linear functional in the theory of distributions. In real-world applications, differentiating discontinuous functions is approximated by first pre-filtering over a smoothing kernel to avoid directly sampling the discontinuity, which is measure zero.

For example, pre-filtering over a 1D box kernel in the x dimension: ϕ˜U [−ϵ, ϵ] results in the following expression:

$$\frac{\partial }{\partial θ} \int H ( {x}^{′} + θ ) ϕ ( x - {x}^{′} ) {dx}^{′} = \int δ ( {x}^{′} + θ ) ϕ ( x - {x}^{′} ) {dx}^{′} = ϕ ( x + θ )$$

The gradient evaluates to

$$\frac{1}{2 ϵ} x + θ ∈ [ - ϵ , ϵ ] ,$$

and 0 elsewhere. Note that because the discontinuity depends on both x and θ, differentiation is performable with respect to θ while pre-filtering along the x axis.

As described above, in some real world scenarios there are one or a few dimensions, on which, parametric discontinuities depend such as time for audio or physics simulation programs, or 2D image axes for shader programs. As a result, the computational challenge of sampling discontinuities in a high dimensional space is reduced by placing samples along these axes, which involve a lower dimension space than the entire parameter space.

The gradient is approximated with respect to each parameter of the program by first prefiltering using a 1D box kernel on the sampling axes. For example, for a continuous function c, an expression H(c (x, θ)) is differentiated and pre-filtered by a kernel ϕ (x) with respect to θ as follows, assuming

$$\frac{d c}{dx} \neq 0$$

at the discontinuity

$${\frac{\partial }{\partial θ} \int H ( c ( {x}^{′} , \vert θ ) ) ϕ ( x - {x}^{′} ) {dx}^{′} = \int \frac{δ ( {x}^{′} - {x}_{d} ) \frac{d c}{d θ}}{\vert \frac{d c}{dx} \vert} ϕ ( x - {x}^{′} ) {x}^{′} = \frac{\frac{d c}{d θ}}{\vert \frac{d c}{dx} \vert} \vert}_{{x}_{d}} ϕ ( x - {x}_{d} )$$

A 1D box (boxcar) kernel is chosen in this example to minimize computations used for locating the discontinuity xd and computing ϕ(x−xd).

### Minimal DSL and Gradient Rules

In this section, a set of programs is defined as expressible in a minimalistic formulation of a domain specific language (DSL). The minimal DSL is described first to simplify the exposition and later is extended to include a ternary if or select function and a ray-marching construct. After presenting the minimal DSL, gradient rules are also presented which can be used to extend a typical reverse-mode automatic differentiation system.

### Minimal DSL Syntax

The set of programs expressible in the minimal DSL is formally defined in this example using a Backus-Naur form. The set of programs expressible in this language are defined as below, where C represents a constant scalar value, x represents a variable that is a sampling axis, θ represents a parameters to be differentiated, and ƒ are continuous atomic functions supported by the DSL, e.g., sin, cos, exp, log, and power where the exponent is a constant.

$${e}_{d} \text{::} = C \vert x \vert θ \vert {e}_{d} + {e}_{d} \vert {e}_{d} \cdot {e}_{d} \vert H ( {e}_{d} ) \vert f ( {e}_{d} )$$

Using the syntax, Dirac parameters are defined as parameters θ, on which, expressions of the form of H(e_{d}) depend.

### Gradient Rules

In the following discussion a pre-filtering process is described that includes use of gradient rules that approximate the derivatives of a pre-filtered function. A function ƒ: dom(ƒ)→ [symbol] is defined that maps a subset of [symbol] to a scalar output in [symbol] . For prefiltering purposes, ƒ is considered to be locally integrable. This framework and implementation support multidimensional outputs [symbol] such as RGB colors for k=3, but since the same gradient process is applied to each output independently, for a simpler notation but without loss of generality a codomain of ƒ is assumable as [symbol] .

In a compiler implementation of the data processing system 104, multidimensional outputs are implemented for efficiency using a single reverse mode pass. The function ƒ is prefiltered by convolving with a box kernel along sampling axis x, giving pre-filtered function ƒ.

$$\hat{f} ( x , \vec{θ} ; ϵ ) = \frac{1}{( α + β ) ϵ} {\int }_{x - αϵ}^{x + βϵ} f ( {x}^{′} , \vec{θ} ) {dx}^{′}$$

Here \vec{θ} is the vector of parameters that are to be differentiated, and α, β are non-negative constants for each pre-filtering with α+β>0, that control the box's location. Discontinuities are located as described above by placing two samples at each end of the kernel support, denoted as ƒ⁺ and ƒ⁻ respectively. When ϵ has a relatively small enough value, ƒ⁺ and ƒ⁻ are viewed as approximating the right and left limit of ƒ. Gradients (i.e., gradient approximations, derivatives) are denoted as ∂k, where k∈{O,AD} that indicates the rules described herein and partial_O is in contrast with conventional auto differentiation (AD) rules. These rules contain a minimum set of operations from which a program from the set e_{d} is composed, e.g., g−h=g+(−1)·h and g/h=g·(h)⁻¹. Boolean operators are rewriteable as compositions of step functions based on De Morgan's law.

### Heaviside Step

Instead of computing ∂g/∂x analytically, this value is approximated in this example using finite difference to avoid extra backpropagation passes. Because g⁺ is computed as an intermediate value as part of the computation of H(g⁺), extra computational passes are not utilized for the finite difference.

### Multiplication

In real world scenarios, programs often generate intermediate values that depend from a same discontinuity and may further interact with each other, leading to multiplications where both arguments are discontinuous. In shader programs, for instance, a lighting model for a three dimensional geometry may depend on discontinuous vectors such as surface normal, point light direction, reflection direction, or half-way vectors. These vectors can be discontinuous at the intersection of different surfaces, at the edge where a foreground object blocks another background object, and so on. When computing the intensity, these vectors are typically normalized first, therefore each of the discontinuous elements n is squared and expressed as n·n. For simplicity of the discussion, assume n is a Heaviside step function and motivate our rule by showing differentiating ƒ=H(x+θ)·H(x+θ) using the AD rule is already incorrect.

As described above, the multiplication rule samples on both sides of the branch, and therefore robustly handles this case.

$$\frac{{\partial }_{O} f}{\partial θ} = \frac{{H}^{+} + {H}^{-}}{2} \frac{1}{\vert 2 ϵ \vert} + \frac{{H}^{+} + {H}^{-}}{2} \frac{1}{\vert 2 ϵ \vert} = \frac{1}{2 ϵ} = \frac{\partial \hat{f}}{\partial θ}$$

### Compiler

The compiler supports functions with multidimensional outputs in [symbol] such as for k=3 for shader programs that output RGB colors. Assuming optimization of a scalar loss L, the gradient is implemented in a single reverse pass for efficiency by first computing the components ∂L/∂ƒⁱ of the Jacobian matrix for each output component ƒⁱ of ƒ, and the backwards pass accumulates (using addition) into ∂L/∂g for each intermediate node g.

In an implementation, the program is evaluated over a regular grid, such as the pixel coordinate grid for shader programs. This supports use of relatively small pre-filtering kernels that span between current and neighboring samples that reflect small discontinuities. The compiler is configured to average between two smaller non-overlapping pre-filtering kernels to reduce a likelihood that a single discontinuity assumption is violated. Specifically, the gradient between U [−Δx, 0] and U [0, Δx] is averaged, where Δx is the sample spacing on the regular grid. This is similar to pre-filtering with U [−Δx, Δx], but allows the compiler to correctly handle discontinuities whose frequency is below a Nyquist limit. For example, if a discontinuous function in a shader program results in a one pixel speckle on the rendered image, the compiler correctly accounts for discontinuities on both sides of the speckle. In the case of a single sampling axis, three samples are drawn along the sampling axis for each location where the gradient is approximated. Furthermore, the samples may be shared between neighboring locations on the regular grid. Additionally, the compiler conservatively avoids incorrect approximation due to multi-discontinuity, e.g., when more than one discontinuity represented by different continuous functions are sampled, the compiler nullifies the contribution from that location by outputting zero gradient.

### Combining Multiple Sampling Axes

It is common for the existence of multiple sampling axes, either because the program can be evaluated on a multi-dimensional grid (e.g. a two dimensional image for the shader applications), or because a single axis is not available that can be used to project every discontinuity.

In an implementation, a separate 1D kernel is used for each sampling axis and gradient approximations are combined from different sampling axes afterwards. For each location, approximations are adaptively chosen from available sampling axes based on the following intuition: the chosen axis is closest to perpendicular to the discontinuity. This supports use of fixed-size steps along the sampling axis that have a larger probability of sampling the discontinuity. In practice, for a discontinuity H(c), this feature is quantified as

$$\vert \frac{\partial c}{\partial x} \vert ,$$

and the axis with the largest value is chosen. For n sampling axes, the compiler draws 2n+1 samples, which are shareable between neighboring locations.

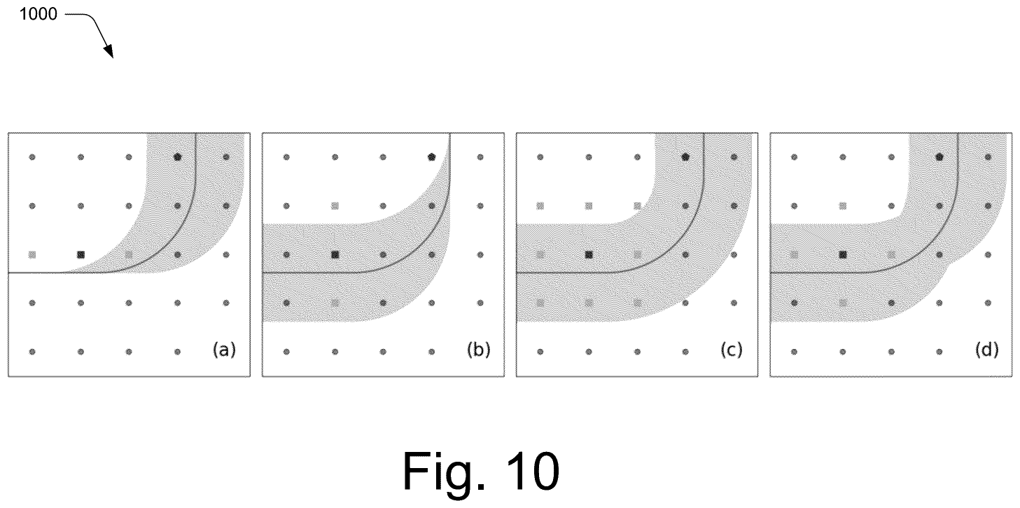

FIG. 10 depicts an example implementation 1000 of visualizing different options for how to combine multiple sampling axes. The line demonstrates a discontinuity, and the shaded region indicates evaluation locations where discontinuity can be sampled. Naively choosing either x at example (a) or the y axis at example (b) can result in a discontinuity parallel to those axes being sampled at measure zero locations. Pre-filtering with a 2D kernel at example (c) allows robust sampling to the discontinuity, but the extra integration introduces an increased computation burden. Implementation at example (d) of the techniques described here support adaptive choices from available axes and ensures discontinuities in any orientation can be sampled with nonzero probability.

### Efficient Ternary Select Operator

In order to robustly handle discontinuities, the multiplication rule places two samples on both ends of the kernel. This leads to extra register usage in compiled GPU kernels that increases a likelihood of register spill, which can result in slower run-times.

To address this technical challenge, the compiler is configured to apply static analysis before multiplication, and resorts to automatic differentiation whenever both arguments are statically continuous. However, the ternary if or select operator can be expressed as multiplications of discontinuous values using the minimum DSL syntax. This is because the branching values can be discontinuous, or the condition is a Boolean expression that is expanded into multiplications of step functions using De Morgan's rule. Therefore, a ternary operator is configured as an extended primitive to the DSL and specialized optimizations are designed so that differentiating uses a similar register space as an automatic differentiation rule.

### Shader Implementation

In this example, the data model configured as gradient approximations are applied to procedural pixel shader programs on optimization tasks that involve finding parameters so that an output of the shader visually corresponds with a target image. Parametric discontinuities are typically present in shaders to control object edges and shape, visibility, and ordering.

Procedural shader programs are typically evaluated over a regular pixel grid, where the workload is parallel. The compiler described herein outputs a gradient program to two backends that both supports highly parallel compute on a graphics processing unit. A TensorFlow (TF) backend utilizes a pre-compiled TF library that allows for fast prototyping and debugging. PyTorch is also supported. A Halide backend on the other hand, grants full control over the kernel scheduling, and can be orders of magnitude faster than TF provided a good schedule.

In the following discussion, a specialized gradient rule is described for a shader-specific programming pattern of implicitly defined geometry, where rules are utilized to reduce a length of a gradient. After that, a random noise technique is described that improves convergence of optimization tasks for shader applications.

### Gradient Rule for Implicitly Defined Geometry

In shader programs, a conventional technique used to define a geometry is to encode it as an implicit surface, or the zero set to some mathematical function, and iteratively estimate ray-geometry intersections, e.g., using ray tracing or sphere tracing loops. While ray marching and sphere tracing loops are programs, and as such can be differentiated using rules described above, this typically results in real world scenarios in an excessively long gradient because the number of loop iterations can be arbitrarily large. As an alternative, to determine the gradient, a root finding process is bypassed to directly approximate a gradient using an implicit function theorem.

The geometry in this example is implicitly defined by a signed distance function that depends on three dimensional locations p and scene parameters \vec{θ}: ƒ(\vec{p}(x,y), \vec{θ})=0. The three dimensional locations further depend on image coordinates (x,y), as the three dimensional location are disposed on the rays casting from a camera to a geometry: \vec{p}=\vec{o}(x,y)+t·\vec{d}(x,y) where o, d, t are camera origin, ray direction, and distance from camera to geometry, respectively. Because x,y are used as sampling axes, the geometry discontinuities are differentiated by pre-filtering along the x axis with an assumption that y is a fixed constant. Given arbitrary \vec{θ}, the discontinuity location x_{d}(\vec{θ}) along x axis can be defined as for a local neighborhood around x_{d}, x<x_{d} and x>x_{d} that evaluates to different branches of the geometry. For silhouettes, this indicates a Boolean operation dependent on whether the ray has hit the geometry and is evaluated differently. For interior edges, this corresponds to ƒ and evaluates to different branches at different sides of x_{d}. Therefore, the discontinuities can be represented as H(x−x_{d}). In the forward pass, a compiler automatically expands a ray marching loop to approach a zero set. The value of x_{d} is not explicitly computed in the program in this example. In a backward pass, the discontinuity is sampled by evaluating Boolean conditions described above, and the backpropagation is carried out by computing ∂x_{d}/∂θᵢ. The compiler is configured to classify a cause of the discontinuity based on whether the camera ray is tangent to the geometry and applies implicit function theorem to each case as described below.

In a case in which a camera ray is tangent to a geometry, ∂x_{d}/∂θ is computed by differentiating with respect to θᵢ on ƒ (\vec{p}, \vec{θ})=0 and combining with

$$< \vec{d} , \frac{\partial f}{\partial \vec{p}} > = 0.$$

$$\frac{\partial {x}_{d}}{\partial {θ}_{i}} = - \frac{\frac{\partial f}{\partial {θ}_{i}} + < \frac{\partial f}{\partial \vec{p}} , \frac{\partial \vec{o}}{\partial {θ}_{i}} + t \frac{\partial \vec{d}}{\partial {θ}_{i}} >}{< \frac{\partial f}{\partial \vec{p}} , \frac{\partial \vec{o}}{\partial {x}_{d}} + t \frac{\partial \vec{d}}{\partial {x}_{d}} >}$$

In a case involving intersection of two surfaces ƒ₀ and ƒ₁, ∂x_{d}/∂θ is computed by applying an implicit function theorem with respect to θ; on both ƒ₀ (\vec{p}, \vec{θ})=0 and at ƒ₁ (\vec{p}, \vec{θ})=0 and cancelling out ∂ₜ/∂θᵢ in both equations.

### Introducing Random Variables to the Optimization

As discussed above, the gradient approximation of the discontinuity is dependent on a ability to sample the discontinuity along the sampling axes. In some instances, however, an assumption that use of a single 2D spatial grid is sufficient for sampling axes may be incorrect, e.g., when a discontinuity makes a discrete choice and the rendered image is exposed to a single branch. For example, when objects overlap, an output color corresponds to the object with the largest Z value. The choice is consistent for each overlapping region. As a result, a discontinuity generated by comparing the Z value between two objects may not be sampled on the current image grid.

To address this technical challenge, auxiliary random variables are introduced. Conceptually the auxiliary random variables function to extend a sampling space to a higher-dimensional space that includes two dimensional spatial parameters and Dirac parameters. For each Dirac parameter, its value is augmented by adding a per pixel uniformly independently distributed random variable whose scale becomes another tunable parameter as well. For the overlapping object example, adding random variables to the Z values leads to speckling color in the overlapping region. Each pair of pixel neighbors with disagreeing color represents a discontinuity on different choices to a Z value comparison. Because the compiler does not have semantic information for each parameter, in practice each Dirac parameter is augmented with an associated random variable. Instead of sampling discontinuities only at an object contour, the random variable supports sampling of the discontinuity at an increased number of pixels.

The data model (e.g., gradient approximation) also generalizes to this random variable setting. Instead of sampling along the image coordinate with regularly spaced samples, samples are generated along a stochastic direction in a parameter space with sample spacing scaled by both spacing e on image grid and the maximum scale s among each of the random variables. Therefore, the width of the pre-filtering kernel is of the form O(ϵ)+O(s). Correspondingly, the error is changed from O(ϵ) to O(ϵ)+O(s): larger scale in the random variable increases an approximation error, but as the scale goes to 0, the error becomes similar to that without the random noise.

### Example System and Device

FIG. 11 illustrates an example system generally at 1100 that includes an example computing device 1102 that is representative of one or more computing systems and/or devices that implement the various techniques described herein. This is illustrated through inclusion of the data processing system 104. The computing device 1102 is configurable, for example, as a server of a service provider, a device associated with a client (e.g., a client device), an on-chip system, and/or any other suitable computing device or computing system.

The example computing device 1102 as illustrated includes a processing device 1104, one or more computer-readable media 1106, and one or more I/O interface 1108 that are communicatively coupled, one to another. Although not shown, the computing device 1102 further includes a system bus or other data and command transfer system that couples the various components, one to another. A system bus can include any one or combination of different bus structures, such as a memory bus or memory controller, a peripheral bus, a universal serial bus, and/or a processor or local bus that utilizes any of a variety of bus architectures. A variety of other examples are also contemplated, such as control and data lines.

The processing device 1104 is representative of functionality to perform one or more operations using hardware. Accordingly, the processing device 1104 is illustrated as including hardware element 1110 that is configurable as processors, functional blocks, and so forth. This includes implementation in hardware as an application specific integrated circuit or other logic device formed using one or more semiconductors. The hardware elements 1110 are not limited by the materials from which they are formed or the processing mechanisms employed therein. For example, processors are configurable as semiconductor(s) and/or transistors (e.g., electronic integrated circuits (ICs)). In such a context, processor-executable instructions are electronically-executable instructions.

The computer-readable storage media 1106 is illustrated as including memory/storage 1112 that stores instructions that are executable to cause the processing device 1104 to perform operations. The memory/storage 1112 represents memory/storage capacity associated with one or more computer-readable media. The memory/storage 1112 includes volatile media (such as random access memory (RAM)) and/or nonvolatile media (such as read only memory (ROM), Flash memory, optical disks, magnetic disks, and so forth). The memory/storage 1112 includes fixed media (e.g., RAM, ROM, a fixed hard drive, and so on) as well as removable media (e.g., Flash memory, a removable hard drive, an optical disc, and so forth). The computer-readable media 1106 is configurable in a variety of other ways as further described below.

Input/output interface(s) 1108 are representative of functionality to allow a user to enter commands and information to computing device 1102, and also allow information to be presented to the user and/or other components or devices using various input/output devices. Examples of input devices include a keyboard, a cursor control device (e.g., a mouse), a microphone, a scanner, touch functionality (e.g., capacitive or other sensors that are configured to detect physical touch), a camera (e.g., employing visible or non-visible wavelengths such as infrared frequencies to recognize movement as gestures that do not involve touch), and so forth. Examples of output devices include a display device (e.g., a monitor or projector), speakers, a printer, a network card, tactile-response device, and so forth. Thus, the computing device 1102 is configurable in a variety of ways as further described below to support user interaction.

Various techniques are described herein in the general context of software, hardware elements, or program modules. Generally, such modules include routines, programs, objects, elements, components, data structures, and so forth that perform particular tasks or implement particular abstract data types. The terms “module,” “functionality,” and “component” as used herein generally represent software, firmware, hardware, or a combination thereof. The features of the techniques described herein are platform-independent, meaning that the techniques are configurable on a variety of commercial computing platforms having a variety of processors.

An implementation of the described modules and techniques is stored on or transmitted across some form of computer-readable media. The computer-readable media includes a variety of media that is accessed by the computing device 1102. By way of example, and not limitation, computer-readable media includes “computer-readable storage media” and “computer-readable signal media.”

“Computer-readable storage media” refers to media and/or devices that enable persistent and/or non-transitory storage of information (e.g., instructions are stored thereon that are executable by a processing device) in contrast to mere signal transmission, carrier waves, or signals per se. Thus, computer-readable storage media refers to non-signal bearing media. The computer-readable storage media includes hardware such as volatile and non-volatile, removable and non-removable media and/or storage devices implemented in a method or technology suitable for storage of information such as computer readable instructions, data structures, program modules, logic elements/circuits, or other data. Examples of computer-readable storage media include but are not limited to RAM, ROM, EEPROM, flash memory or other memory technology, CD-ROM, digital versatile disks (DVD) or other optical storage, hard disks, magnetic cassettes, magnetic tape, magnetic disk storage or other magnetic storage devices, or other storage device, tangible media, or article of manufacture suitable to store the desired information and are accessible by a computer.

“Computer-readable signal media” refers to a signal-bearing medium that is configured to transmit instructions to the hardware of the computing device 1102, such as via a network. Signal media typically embodies computer readable instructions, data structures, program modules, or other data in a modulated data signal, such as carrier waves, data signals, or other transport mechanism. Signal media also include any information delivery media. The term “modulated data signal” means a signal that has one or more of its characteristics set or changed in such a manner as to encode information in the signal. By way of example, and not limitation, communication media include wired media such as a wired network or direct-wired connection, and wireless media such as acoustic, RF, infrared, and other wireless media.

As previously described, hardware elements 1110 and computer-readable media 1106 are representative of modules, programmable device logic and/or fixed device logic implemented in a hardware form that are employed in some embodiments to implement at least some aspects of the techniques described herein, such as to perform one or more instructions. Hardware includes components of an integrated circuit or on-chip system, an application-specific integrated circuit (ASIC), a field-programmable gate array (FPGA), a complex programmable logic device (CPLD), and other implementations in silicon or other hardware. In this context, hardware operates as a processing device that performs program tasks defined by instructions and/or logic embodied by the hardware as well as a hardware utilized to store instructions for execution, e.g., the computer-readable storage media described previously.

Combinations of the foregoing are also be employed to implement various techniques described herein. Accordingly, software, hardware, or executable modules are implemented as one or more instructions and/or logic embodied on some form of computer-readable storage media and/or by one or more hardware elements 1110. The computing device 1102 is configured to implement particular instructions and/or functions corresponding to the software and/or hardware modules. Accordingly, implementation of a module that is executable by the computing device 1102 as software is achieved at least partially in hardware, e.g., through use of computer-readable storage media and/or hardware elements 1110 of the processing device 1104. The instructions and/or functions are executable/operable by one or more articles of manufacture (for example, one or more computing devices 1102 and/or processing devices 1104) to implement techniques, modules, and examples described herein.

The techniques described herein are supported by various configurations of the computing device 1102 and are not limited to the specific examples of the techniques described herein. This functionality is also implementable all or in part through use of a distributed system, such as over a “cloud” 1114 via a platform 1116 as described below.

The cloud 1114 includes and/or is representative of a platform 1116 for resources 1118. The platform 1116 abstracts underlying functionality of hardware (e.g., servers) and software resources of the cloud 1114. The resources 1118 include applications and/or data that can be utilized while computer processing is executed on servers that are remote from the computing device 1102. Resources 1118 can also include services provided over the Internet and/or through a subscriber network, such as a cellular or Wi-Fi network.

The platform 1116 abstracts resources and functions to connect the computing device 1102 with other computing devices. The platform 1116 also serves to abstract scaling of resources to provide a corresponding level of scale to encountered demand for the resources 1118 that are implemented via the platform 1116. Accordingly, in an interconnected device embodiment, implementation of functionality described herein is distributable throughout the system 1100. For example, the functionality is implementable in part on the computing device 1102 as well as via the platform 1116 that abstracts the functionality of the cloud 1114.

In implementations, the platform 1116 employs a “machine-learning model” that is configured to implement the techniques described herein. A machine-learning model refers to a computer representation that can be tuned (e.g., trained and retrained) based on inputs to approximate unknown functions. In particular, the term machine-learning model can include a model that utilizes algorithms to learn from, and make predictions on, known data by analyzing training data to learn and relearn to generate outputs that reflect patterns and attributes of the training data. Examples of machine-learning models include neural networks, convolutional neural networks (CNNs), long short-term memory (LSTM) neural networks, decision trees, and so forth.

Although the invention has been described in language specific to structural features and/or methodological acts, it is to be understood that the invention defined in the appended claims is not necessarily limited to the specific features or acts described. Rather, the specific features and acts are disclosed as example forms of implementing the claimed invention.

What is claimed is:

1. A method comprising:
receiving, by a processing device, a program having a computing function that includes a discontinuity;
receiving, by the processing device, an input identifying an axis;
generating, by the processing device, a plurality of samples oriented along the axis based on an output of the program;
generating, by the processing device, a data model of the program based on the plurality of samples, the generating including modeling the discontinuity of the computing function based on the plurality of samples; and
outputting, by the processing device, the data model including the modeled discontinuity.

2. The method as described in claim 1, wherein the generating the data model includes modeling the discontinuity based on the plurality of samples using a 1D box kernel.

3. The method as described in claim 1, wherein the generating of the data model converts a sequence of primitive operations of the computing function of the program into one or more gradients.

4. The method as described in claim 1, wherein the generating the data model is performed automatically and without user intervention.

5. The method as described in claim 1, wherein the modeling the discontinuity is based on pairs of samples taken from the plurality of samples.

6. The method as described in claim 5, wherein the modeling of the discontinuity estimates one or more gradients at locations between the pairs of samples.

7. The method as described in claim 6, wherein the one or more gradients are generated as one or more derivatives of the computing function.

8. The method as described in claim 1, wherein the discontinuity is caused by an if/else branch in the program.

9. The method as described in claim 1, further comprising executing a machine learning model using the data model.

10. The method as described in claim 9, wherein the executing of the machine learning model uses the data model as part of a backpropagation operation.

11. A system comprising:
an axis sampling module implemented by a processing device to generate a plurality of samples from a program that includes a computing function having a discontinuity; and
a data model generation module implemented by the processing device to generate a data model, automatically and without user intervention, based on the plurality of samples as one or more gradients having the discontinuity modeled using a 1D box kernel.

12. The system as described in claim 11, wherein the data model includes a sequence of primitive operations converted from the computing function of the program based on the samples and the discontinuity is caused by an if/else branch in the program.

13. The system as described in claim 11, wherein the one or more gradients are generated as one or more derivatives of the computing function.

14. The system as described in claim 11, wherein the data model generation module is configured to model the discontinuity based on pairs of samples taken from the plurality of samples.

15. The system as described in claim 14, wherein the data model generation module is configured to model the discontinuity by estimating gradients at locations between the pairs of samples.

16. The system as described in claim 11, further comprising executing a data model execution system configured to execute a machine learning model using the data model as part of a backpropagation operation between layers of the machine learning model.

17. A computing device comprising:
a processing device; and
a computer-readable storage medium storing instructions that, responsive to execution by the processing device, causes the processing device to perform operations including:
generating samples oriented along an axis based on an output of a program having a computing function that includes a discontinuity;
generating one or more gradients that model the discontinuity of the computing function based on the samples; and
backpropagating the one or more gradients between layers as part of executing a machine learning model.

18. The computing device as described in claim 17, further comprising receiving an input defining the axis.

19. The computing device as described in claim 17, wherein the generating of the one or more gradients models the discontinuity based on pairs of the samples.

20. The computing device as described in claim 17, wherein the machine learning model is configured to perform an image processing operation.
